(19) United States
(12) Patent Application Publication
(10) Pub. No.: US 2004/0263156 A1
(43) Pub. Date: Dec. 30, 2004

(54) Magnetoresistive angle sensor

(76) Inventors: Reinhard Buchhold, Hamburg (DE); Adrian Harmansa, Hamburg (DE)

Correspondence Address: Philips Electronics North America Corporation, Corporate Patent Counsel, PO Box 3001, Briarcliff Manor, NY, 10510, US

(21) Appl. No.: 10/487,205

(22) PCT Filed: Aug. 22, 2002
(86) PCT No.: PCT/IB02/03463

(30) Foreign Application Priority Data
Sep. 23, 2001 (DE) 101 41 372.6

(51) Int. Cl. G01B 7/14; G01R 33/06

(52) U.S. Cl. 324/207.21

(57) ABSTRACT

To provide a magnetoresistive angle sensor comprising a sensor element arranged within a homogeneous, permanent magnetic field, which sensor has a simple structure and is distinguished by its low sensitivity to errors, a magnet source providing the magnetic field is encapsulated (shielded) from the exterior.

### FIELD OF THE INVENTION

The invention relates to a magnetoresistive angle sensor comprising a sensor element arranged within a homogeneous, permanent magnetic field.

### BACKGROUND OF THE INVENTION

Magnetoresistive angle sensors of the type described above are generally known. They are suitable for contactless angle measurement. To this end, the homogeneous, permanent magnetic field surrounding the sensor element is rotated about a fixed axis. The resultant vector of the magnetic field thereby changes with respect to a sensing direction of the sensor element. An output signal of the sensor element is then proportional to the angle of the resultant vector so that a corresponding output signal (angle signal) can be provided.

The homogeneous, permanent magnetic field is usually provided by a ring magnet surrounding the sensor element. This has the drawback that the homogeneous, permanent magnetic field within the ring magnet is affected by accidental or required presence of magnetizable components in the ambience of the magnetoresistive angle sensor. This leads to a relatively large error sensitivity of the magnetoresistive angle sensor.

### OBJECT AND SUMMARY OF THE INVENTION

It is an object of the invention to provide a magnetoresistive angle sensor of the type described, which has a simple structure and is distinguished by its low sensitivity to errors.

According to the invention, this object is solved by a magnetoresistive angle sensor of the type defined in claim 1. Since a source providing the homogeneous, permanent magnetic field is encapsulated from the exterior, it is advantageously achieved that the magnetic field cannot emerge externally from the magnetoresistive angle sensor and may thus be affected by magnetizable components which are accidentally or necessarily present in the proximity of the angle sensor. The homogeneity of the magnetic field within the magnetoresistive angle sensor is thereby maintained. Magnetizable components in the ambience thus do not lead to failure of the sensor signal. Since the field is concentrated within the enclosure, comparatively large magnetic field strengths act on the angle sensor so that failing influences on the measuring result of the sensor are also reduced. Moreover, in addition to the shielding of the magnetic field, it is advantageous that the encapsulation of the magnetic field source, particularly when it is constituted by a relatively brittle permanent ring magnet, yields an effective mechanical protection of the angle sensor.

In a preferred embodiment of the invention, the permanent magnet source is a ring magnet and the encapsulation is constituted by a ring element surrounding the ring magnet. A very simple and space-saving way of encapsulating the magnetic field source can thereby be achieved. Particularly when the outer cladding of the permanent ring magnet is connected in a form-locking manner to an inner cladding of the ring element, the magnetic field is effectively prevented from emerging to the exterior of the ring magnet.

In a further preferred embodiment of the invention, the ring element consists of a soft-magnetic material. This reliably ensures that an emergence of the magnetic field from the magnetic field source to the exterior is not possible.

### BRIEF DESCRIPTION OF THE DRAWINGS

These and other aspects of the invention are apparent from and will be elucidated with reference to the embodiments described hereinafter.

In the drawings:

FIG. 1 is a diagrammatic elevational view of a magnetoresistive angle sensor;

FIG. 2 shows a magnetic field variation of an angle sensor in accordance with the state of the art;

FIG. 3 shows a magnetic field variation of a disturbed angle sensor in accordance with the state of the art, and

FIG. 4 shows a magnetic field variation of an angle sensor according to the invention.

### DESCRIPTION OF EMBODIMENTS

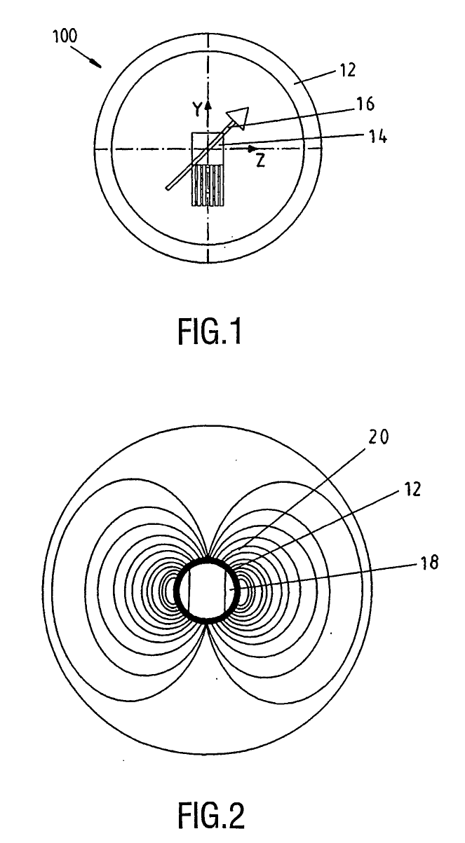

FIG. 1 shows diagrammatically the mode of operation of a magnetoresistive angle sensor 100. The angle sensor 100 comprises a permanent ring magnet 12 constituting a magnetic field source, which coaxially surrounds a magnetoresistive sensor element 14. An angle measurement is possible in an indicated x/y plane which coincides with the plane of the drawing in this case. In accordance with the magnetic field exerted by the ring magnet 12 on the magnetoresistive sensor element 14, a resultant vector 16 of the magnetic field in the x/y plane of the sensor is obtained. When the ring magnet 12 is rotated about the z axis for a contactless angle measurement, a change of the angle between the resultant vector 16 and a fixed, defined axis, for example, the x axis or the y axis of the angle sensor 100 is obtained. In accordance with this resultant angle position of the vector 16, a proportional output voltage of the sensor element 14 can be derived and evaluated.

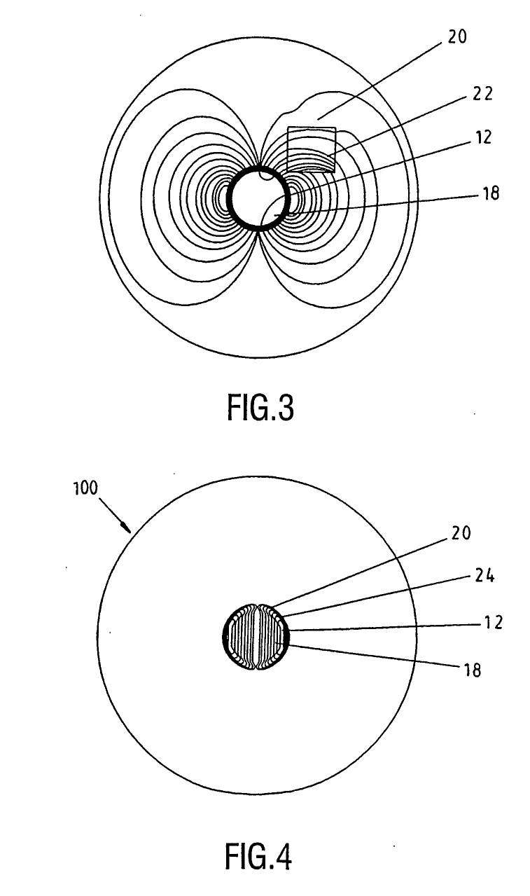

FIG. 2 shows diagrammatically the variation of the magnetic field supplied by the ring magnet 12. A homogeneous magnetic field, i.e. a magnetic field having parallel magnetic field lines is obtained in an inner space 18 of the ring magnet 12. The magnetic circuit is closed in the ambience 20 of the ring magnet 12. When a magnetizable component 22 comes in the ambience of the ring magnet 12—as is shown diagrammatically in FIG. 3-, the magnetic field is influenced so that the homogeneity of the magnetic field is disturbed in the inner space 18. This affects the accuracy of the angle sensor 100.

FIG. 4 shows diagrammatically the angle sensor 100 according to the invention. In this angle sensor, the ring magnet 12 is surrounded by a ring element 24 constituting an encapsulation. The ring element 24 is coaxial with respect to the ring magnet 12 so that an outer cladding of the ring magnet 12 engages an inner cladding of the ring element 24. The diameters of the ring magnet 12 and the ring element 24 are adapted to each other in such a way that there is no air gap. Ring element 24 and ring magnet 12 are preferably glued together so that a flexible connection is obtained. The ring element 24 consists of a soft-magnetic material.

As a result of the arrangement of the ring element 24, the magnetic field of the ring magnet 12 does not reach the ambience 20 beyond the ring element 24. There is a quasi-concentration in the ring element 24. The magnetic circuit is closed via the ring element 24.

With an assumed equal remanence of the ring magnet 12 with respect to an arrangement without a ring element 24, there is a significant increase of the magnetic field strength in the inner space 18 of the angle sensor 100. In FIG. 2, this is illustrated by the fatter straight (homogeneous) magnetic field lines in the inner space 18.

Assuming, by way of example, that the ring magnet 12 has an inner diameter of 10 mm, a wall strength of 1 mm as well as a remanence of 1 T, a magnetic field strength of 10 kA/m in the inner space 18 is obtained for the arrangement shown in FIG. 2.

By arranging a ring element 24 with an assumed wall strength of 1 mm and an assumed relative permeability of 1000, the magnetic field strength in the inner space 18 is increased to about 100 kA/m.

It is thus clear that the arrangement of the ring element 24 according to the invention enhances the accuracy and the insensitivity to disturbances of the magnetoresistive angle sensor 100 for contactless angle measurement. Magnetizable components 22 situated in the ambience 20 no longer lead to a detrimental effect on the magnetic field in the inner space 18.

1. A magnetoresistive angle sensor comprising a sensor element arranged within a homogeneous, permanent magnetic field, characterized in that a magnet source providing the magnetic field is encapsulated (shielded) from the exterior.

2. A magnetoresistive angle sensor as claimed in claim 1, characterized in that the magnet source is a permanent ring magnet (12) which is arranged coaxially to the sensor element (14).

3. A magnetoresistive angle sensor as claimed in claim 1, characterized in that the encapsulation is constituted by a ring element (24) surrounding the ring magnet (12).

4. A magnetoresistive angle sensor as claimed in claim 3, characterized in that an outer cladding of the ring magnet (12) is connected flexibly and without an air gap to an inner cladding of the ring element (24).

5. A magnetoresistive angle sensor as claimed in claim 4, characterized in that the ring magnet (12) and the ring element (24) are glued together.

6. A magnetoresistive angle sensor as claimed in claim 1, characterized in that the ring element (24) consists of a soft-magnetic material.
